(19) United States
(12) Patent Application Publication
(10) Pub. No.: US 2025/0324551 A1
(43) Pub. Date: Oct. 16, 2025

(54) Optoelectronics Transceiver Device

(71) Applicant: Formerica OptoElectronics Inc., Hsinchu County (TW)

(72) Inventors: Peter Sin-Te Liu, Hsinchu County (TW); Joseph Chen-Kwo Liu, Hsinchu County (TW); Jack Hung-Fu Yeh, Hsinchu County (TW); Justin Chih-Chun Chiang, Hsinchu County (TW)

(21) Appl. No.: 19/176,571

(22) Filed: Apr. 11, 2025

Related U.S. Application Data
(60) Provisional application No. 63/633,122, filed on Apr. 12, 2024.

(30) Foreign Application Priority Data
Apr. 11, 2025 (TW) 114113857

(51) Int. Cl. H05K 7/20

(52) U.S. Cl. CPC H05K 7/2039

(57) ABSTRACT

An optoelectronics transceiver device, and the optoelectronics transceiver device comprises an optoelectronics transceiver module and an encapsulation film. The optoelectronics transceiver module comprises an optoelectronics transceiver module processing section, and the encapsulation film covers the processing section to provide a sealed operating environment. In this way, when the optoelectronics transceiver device operates in a cooling liquid, the encapsulation film can prevent the cooling liquid from seeping into the optoelectronics transceiver device and affecting the optoelectronics conversion of the optoelectronics transceiver module, thereby effectively improving the operational efficiency and service life of the optoelectronics transceiver device.

### CROSS-REFERENCE TO RELATED APPLICATIONS

This application claims the priority of U.S. Patent Application No. 63/633,122 filed on Apr. 12, 2024 and the priority of Republic of China Patent Application No. 114113857 filed on Apr. 11, 2025, in the State Intellectual Property Office of the R.O.C., the disclosure of which is incorporated herein by reference.

### BACKGROUND OF THE INVENTION

### Field of the Invention

The present application relates to an optical communication device, and more particularly to an optoelectronics transceiver device capable of preventing cooling liquid from seeping in and affecting operation.

### Descriptions of the Related Art

With the rapid development of network technology, optical communication technology has gradually replaced traditional electrical communication technology used for signal transmission due to its advantages, comprising high transmission speed, long transmission distance, resistance to electromagnetic interference, and high security. Therefore, optical communication technology has become a mainstream communication technology in modern development and is widely applied in information communication among various optical fiber network devices.

Optical fiber network devices in the optical communication industry are often equipped with optoelectronics transceiver devices, which perform optical-electrical signal conversing to convert electrical signals into optical signals or vice versa, thereby enabling high-capacity and high-speed signal transmission for optical fiber network devices. It should be noted that common types of optoelectronics transceiver devices comprise the SFP series (Small Form-Factor Pluggable), QSFP series (Quad Small Form-Factor Pluggable), QSFP-DD series (Quad Small Form-Factor Pluggable Double Density), and OSFP series (Octal Small Form-Factor Pluggable).

Furthermore, as optical fiber network devices typically operate continuously for extended periods, their operating temperatures tend to rise, necessitating effective heat dissipation. To achieve this, optical fiber network devices are often immersed in high thermal conductivity cooling liquids, allowing them to operate in a liquid-based cooling environment. This setup enables the cooling liquid to rapidly dissipate the heat generated by the operation of the devices, thereby enhancing the performance and extending the service life of the optical fiber network devices.

However, when the optical fiber network devices are immersed in the cooling liquid, the optoelectronics transceiver devices used in conjunction with them must also be immersed. Therefore, if the waterproof performance of the optoelectronics transceiver device is inadequate, the cooling liquid may seep into the device and adversely affect signal transmission.

In view of the above, how to improve the waterproof performance of the optoelectronics transceiver device to prevent the cooling liquid from seeping into the device is a problem that urgently needs to be addressed by those skilled in the art.

### SUMMARY OF THE INVENTION

In view of the aforementioned issues in the prior art, the primary objective of the present application is to provide an optoelectronics transceiver device that, while being cooled by a cooling liquid, is also capable of preventing the cooling liquid from seeping into the optoelectronics transceiver device.

To achieve the above and other objectives, the present application provides an optoelectronics transceiver device, which is configured to transmit a signal, wherein the optoelectronics transceiver device comprises: an optoelectronics transceiver module, which comprises an optoelectronics transceiver module processing section, and the optoelectronics transceiver module processing section is configured to perform optoelectronics transceiver processing on the signal; a device base, which comprises a base internal space, and the device base is configured to carry the optoelectronics transceiver module, allowing the optoelectronics transceiver module processing section to be accommodated in the base internal space; an adhesive, which is filled into the base internal space to form a sealing subspace within the base internal space, wherein the optoelectronics transceiver module processing section is located in the sealing subspace, and the sealing subspace provides a sealed operating environment for the optoelectronics transceiver module processing section; and an encapsulation film, which covers the optoelectronics transceiver module processing section within the base internal space to separate the adhesive from the optoelectronics transceiver module processing section.

Preferably, the optoelectronics transceiver device said above, further comprising a first cooling component, and the first cooling component is located in the sealing subspace and is in contact with the optoelectronics transceiver module processing section to absorb heat and cool the optoelectronics transceiver module processing section; and the encapsulation film also covers the first cooling component to separate the adhesive from the first cooling component.

Preferably, the optoelectronics transceiver device said above, wherein the first cooling component is a water block and comprises a first cooling component liquid passage, and the first cooling component liquid passage is configured to allow cooling liquid to flow to cool the optoelectronics transceiver module processing section.

Preferably, the optoelectronics transceiver device said above, wherein the device base comprises a frame-shaped or U-shaped cross section.

Preferably, the optoelectronics transceiver device said above, wherein the first cooling component is a heat-conductive metal component.

Preferably, the optoelectronics transceiver device said above, further comprising a device cover, and the device cover is disposed on the device base so as to allow the adhesive to be located in the signal base internal space.

Preferably, the optoelectronics transceiver device said above, further comprising a second cooling component, which is located in the base internal space, one end of the second cooling component penetrates through the encapsulation film and is in contact with the optoelectronics transceiver module processing section to absorb heat from the optoelectronics transceiver module processing section, and the other end of the second cooling component penetrates through the adhesive and is in contact with the device cover to conduct the absorbed heat to the outside through the device cover, thereby achieving cooling of the optoelectronics transceiver module processing section.

Preferably, the optoelectronics transceiver device said above, wherein the device base is in contact with the device cover to absorb heat and cool the device cover.

Preferably, the optoelectronics transceiver device said above, wherein the device base is a heat-conductive metal base; the second cooling component is a heat-conductive metal component; and the device cover is a heat-conductive metal cover.

Preferably, the optoelectronics transceiver device said above, further comprising a signal optical cable, and the signal optical cable penetrates through the adhesive and the encapsulation film to connect to the optoelectronics transceiver module processing section for transmitting the signal.

Preferably, the optoelectronics transceiver device said above, which is configured to be equipped with an optical fiber network equipment, wherein the optoelectronics transceiver module further comprises an optoelectronics transceiver module joining section, the device base comprises a base joining port, and the optoelectronics transceiver module joining section is located at the base joining port to provide joining to the optical fiber network equipment, and the optoelectronics transceiver device further comprises a stopper body, and the stopper body is located between the base internal space and the base joining port to block the adhesive from entering the base joining port from the base internal space.

Preferably, the optoelectronics transceiver device said above, wherein the stopper body and the device base are integrally formed.

In addition, the present application further provides an optoelectronics transceiver device, which is configured to transmit a signal, wherein the optoelectronics transceiver device comprises: an optoelectronics transceiver module, comprising an optoelectronics transceiver module processing section, and the optoelectronics transceiver module processing section is configured to perform optoelectronics transceiver processing on the signal; and an encapsulation film, which covers the optoelectronics transceiver module processing section to form a sealing subspace, wherein the optoelectronics transceiver module processing section is located in the sealing subspace, and the sealing subspace provides a sealed operating environment for the optoelectronics transceiver module processing section.

Compared with the prior art, the optoelectronics transceiver device of the present application comprises an optoelectronics transceiver module and an encapsulation film. The optoelectronics transceiver module comprises an optoelectronics transceiver module processing section, and the encapsulation film covers the optoelectronics transceiver module processing section to provide a sealed operating environment for the optoelectronics transceiver module processing section. In this way, when the optoelectronics transceiver device operates in a cooling liquid, the encapsulation film can prevent the cooling liquid from seeping into the optoelectronics transceiver module processing section and affecting the optical-electrical conversing of the optoelectronics transceiver module, thereby effectively improving the operational efficiency and service life of the optoelectronics transceiver device.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic view showing the state of the optoelectronics transceiver device of the present application being immersed in a cooling liquid.

FIG. 2 is a perspective schematic view showing partial components of the optoelectronics transceiver device of the present application from a first viewing angle in one embodiment.

FIG. 3 is a perspective schematic view showing partial components of the optoelectronics transceiver device of the present application from a second viewing angle in one embodiment.

FIG. 4 is a schematic view showing partial components of the optoelectronics transceiver device of the present application being immersed in a cooling liquid.

FIG. 5 is a schematic view showing partial components of the optoelectronics transceiver device of the present application being immersed in a cooling liquid.

FIG. 6 is a schematic view showing partial components of the optoelectronics transceiver device of the present application being immersed in a cooling liquid.

FIG. 7 is a cross-sectional schematic view showing partial components of the optoelectronics transceiver device of the present application in one embodiment.

FIG. 8 is a cross-sectional schematic view showing partial components of the optoelectronics transceiver device of the present application in one embodiment.

### THE PREFERRED DETAILED DESCRIPTION OF EMBODIMENT

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In addition, it should be noted that, for the sake of clarity and simplicity of disclosure, the same reference numerals will be used to denote components having the same or similar functions in the following embodiments, and descriptions of identical or equivalent features will be omitted.

The present application provides an optoelectronics transceiver device, which can be disposed in an optical fiber network device and can operate in a cooling liquid along with the optical fiber network device. The optoelectronics transceiver device comprises an optoelectronics transceiver module and an encapsulation film. The optoelectronics transceiver module comprises an optoelectronics transceiver module processing section, and the encapsulation film covers the optoelectronics transceiver module processing section to provide a sealed operating environment. In this way, when the optoelectronics transceiver device operates in a cooling liquid, the encapsulation film can prevent the cooling liquid from seeping into the optoelectronics transceiver module processing section and affecting the operation of the optoelectronics transceiver module.

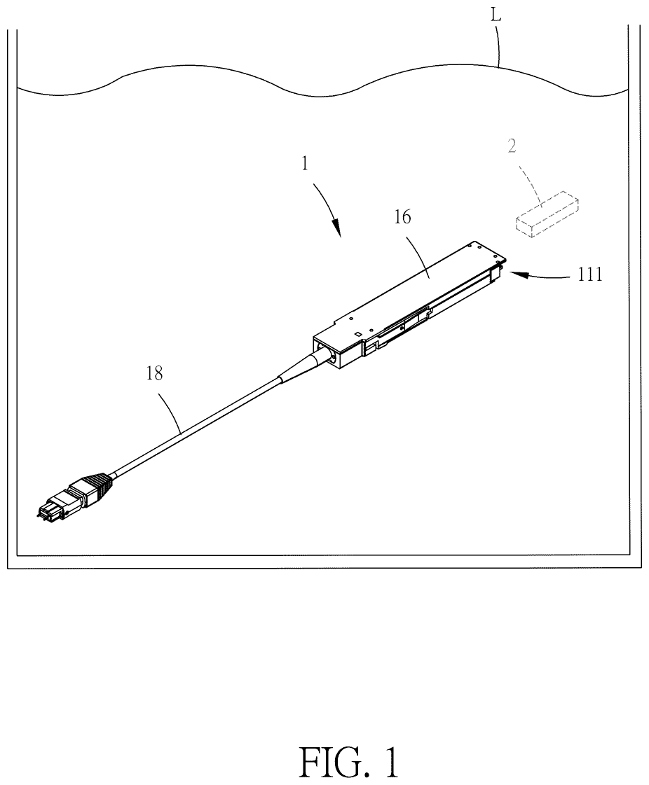

For a detailed description of the embodiments disclosed in the present application, please refer to FIGS. 1 to 8.

In the embodiments shown in FIGS. 1 to 8, an optoelectronics transceiver device 1 is provided. The optoelectronics transceiver device 1 is configured to transmit a signal and to be used with an optical fiber network device 2. The optoelectronics transceiver device 1 comprises: an optoelectronics transceiver module 11, a device base 12, an adhesive 13, an encapsulation film 14, a device cover 16, and a signal optical cable 18.

It should be noted that the optical fiber network device 2 can be immersed in a cooling liquid L which has high thermal conductivity, allowing the optical fiber network device 2 to operate in a liquid cooling environment. The cooling liquid can quickly dissipate the heat generated by the operation of the optical fiber network device 2, thereby enhancing its performance and service life. Accordingly, the optoelectronics transceiver device 1 can also be immersed in the cooling liquid L along with the optical fiber network device 2.

Regarding the optoelectronics transceiver module 11, comprising an optoelectronics transceiver module processing section 111 and an optoelectronics transceiver module joining section 112. The processing section 111 is configured to convert the signal, which refers to converting an electrical signal into an optical signal or converting the optical signal into an electrical signal. The joining section 112 is configured to join with the optical fiber network device 2 to transmit the signal to the optical fiber network device 2.

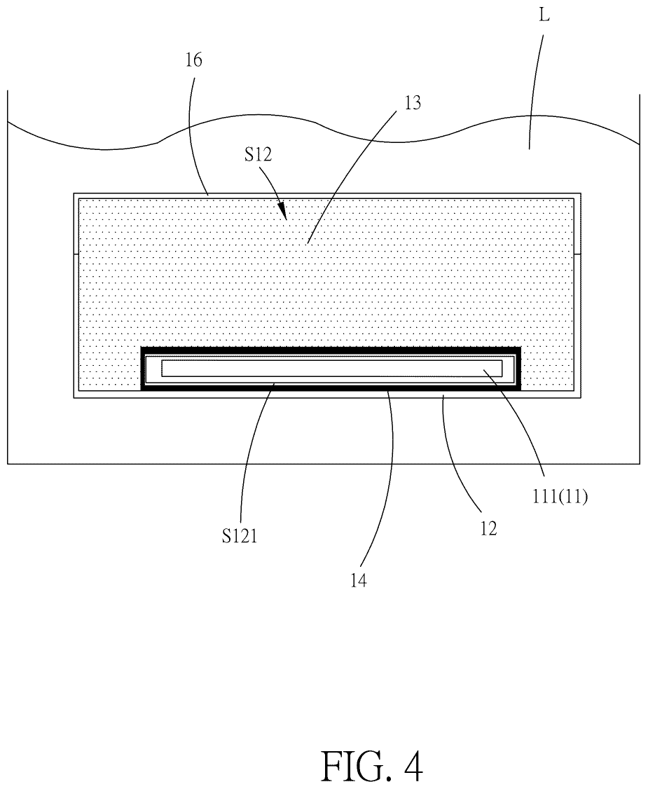

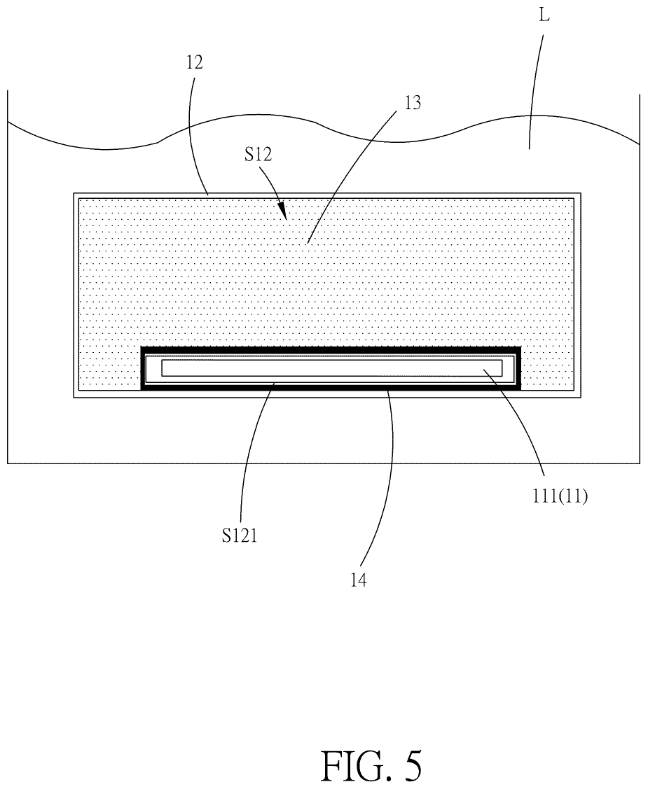

Regarding the device base 12, comprising a base internal space S12 and a base joining port P121. The device base 12 carries the optoelectronics transceiver module 11 to allow the optoelectronics transceiver module processing section 111 to be accommodated in the base internal space S12, and the joining section 112 is positioned at the base joining port P121 to join with the optical fiber network device 2. As shown in FIG. 5, the device base 12 comprises a frame-shaped cross section forming the base internal space S12. However, this is not limited thereto. For example, as shown in FIG. 4, the device base 12 may have a U-shaped cross section forming the base internal space S12.

Regarding the adhesive 13, and the adhesive 13 is filled into the base internal space S12 to form a sealing subspace S121. The processing section 111 is located in the sealing subspace S121, and the sealing subspace S121 provides a sealed operating environment for the optoelectronics transceiver module processing section 111. Therefore, when the optoelectronics transceiver device 1 is immersed in the cooling liquid L along with the optical fiber network device 2, the adhesive 13 can prevent the cooling liquid L from seeping into the sealing subspace S121, thereby improving the waterproof performance of the optoelectronics transceiver device 1.

It should be noted that in the above embodiment, the adhesive 13 may be, but is not limited to, an epoxy adhesive. In addition, the optoelectronics transceiver module 11 can perform optical-electrical conversing in the sealing subspace S121. Thus, when the optoelectronics transceiver device 1 operates immersed in the cooling liquid L, the adhesive 13 can prevent the cooling liquid L from affecting the conversing operation of the optoelectronics transceiver module 11, thereby effectively improving the operational efficiency and service life of the optoelectronics transceiver device 1.

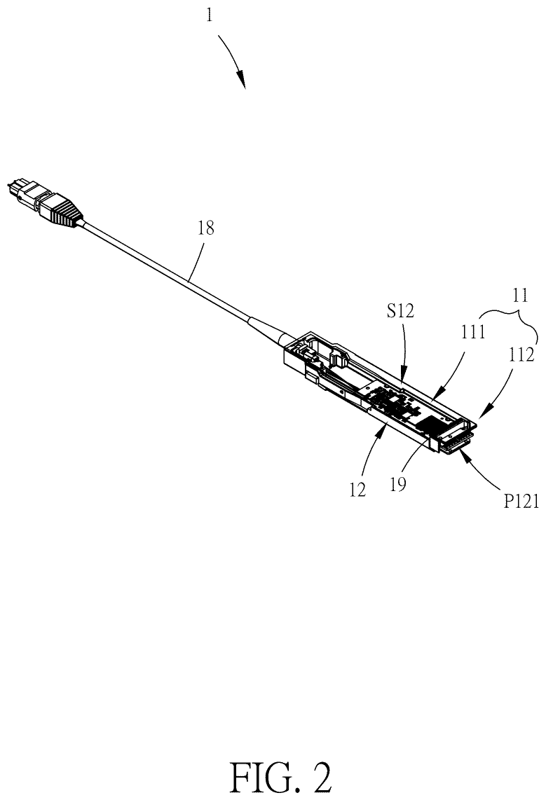

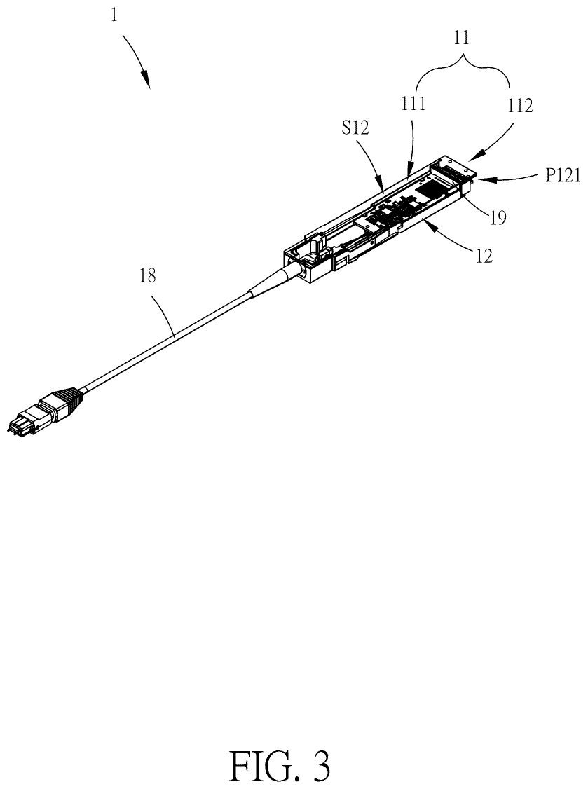

In the embodiments shown in FIGS. 2 to 3, the optoelectronics transceiver device 1 further comprises a stopper body 19, which is located between the base internal space S12 and the base joining port P121 to block the adhesive 13 from entering the base joining port P121 from the base internal space S12. It should be noted that the stopper body 19 and the device base 12 may optionally be integrally formed or separately formed.

Regarding the encapsulation film 14, it covers the optoelectronics transceiver module processing section 111 within the base internal space S12 to separate the adhesive 13 from the optoelectronics transceiver module processing section 111. Accordingly, the encapsulation film 14 can prevent the adhesive 13 from adhering to the optoelectronics transceiver module processing section 111, thereby avoiding any adverse effect of the adhesive 13 on the optoelectronics transceiver module processing section 111.

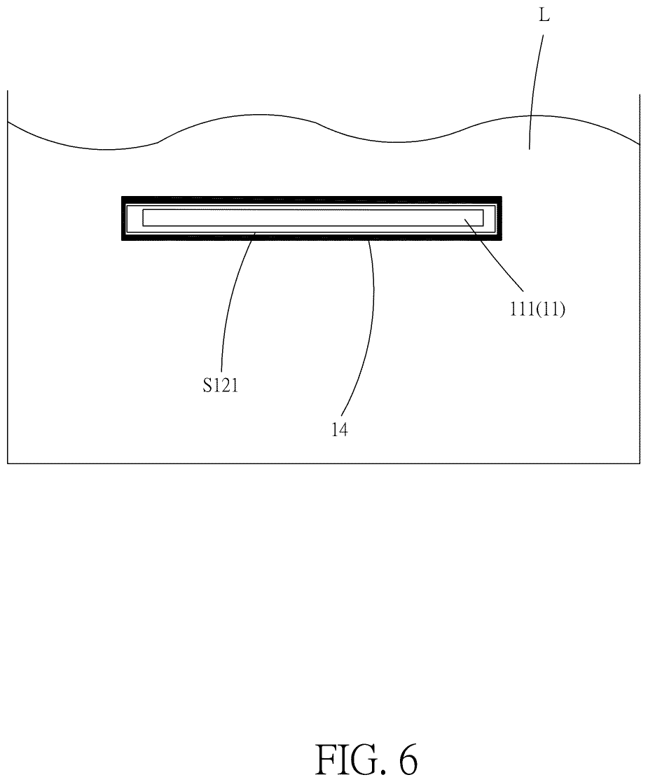

It should be noted that, in the embodiment shown in FIG. 6, the adhesive 13 may be omitted, and the encapsulation film 14 may optionally cover the optoelectronics transceiver module processing section 111 to form a sealing subspace S121. The processing section 111 is located in the sealing subspace S121, which provides a sealed operating environment. Therefore, when the optoelectronics transceiver device 1 is immersed in the cooling liquid L along with the optical fiber network device 2, the encapsulation film 14 can prevent the cooling liquid L from seeping into the sealing subspace S121, thereby enhancing the waterproof performance of the optoelectronics transceiver device 1.

Regarding the device cover 16, it is disposed on the device base 12. In the above embodiment, the device cover 16 may limit the position of the adhesive 13 to shield the signal base internal space S12, so that the adhesive 13 is located within the signal base internal space S12, thereby maintaining a neat appearance.

Regarding the signal optical cable 18, it may pass through the adhesive 13 and the encapsulation film 14 to connect to the optoelectronics transceiver module processing section 111 for transmitting the signal. It should be noted that the signal optical cable 18 comprises a signal optical cable fiber core, which may be made of glass or plastic and is configured to transmit the signal.

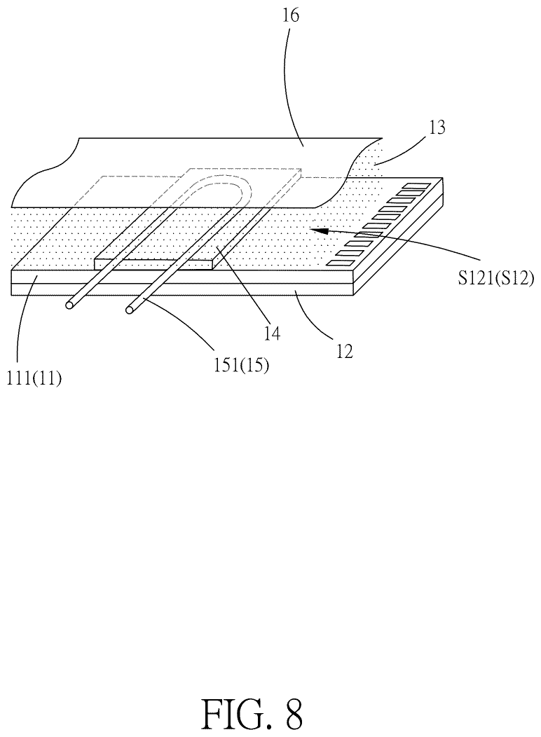

In the embodiment shown in FIG. 8, the optoelectronics transceiver device 1 further comprises a first cooling component 15. The first cooling component 15 is located in the sealing subspace S121 and is in contact with the optoelectronics transceiver module processing section 111 to absorb heat therefrom and achieve cooling. Accordingly, the encapsulation film 14 may also cover the first cooling component 15 to separate the first cooling component 15 from the adhesive 13 and prevent the adhesive 13 from adhering to the first cooling component 15.

Preferably, the first cooling component 15 may be a heat-conductive metal component for conducting heat from the optoelectronics transceiver module processing section 111. In addition, the first cooling component 15 may be a water block and comprise a first cooling component liquid passage 151, and the first cooling component liquid passage 151 allows cooling liquid to flow and conduct heat from the optoelectronics transceiver module processing section 111, thereby achieving cooling.

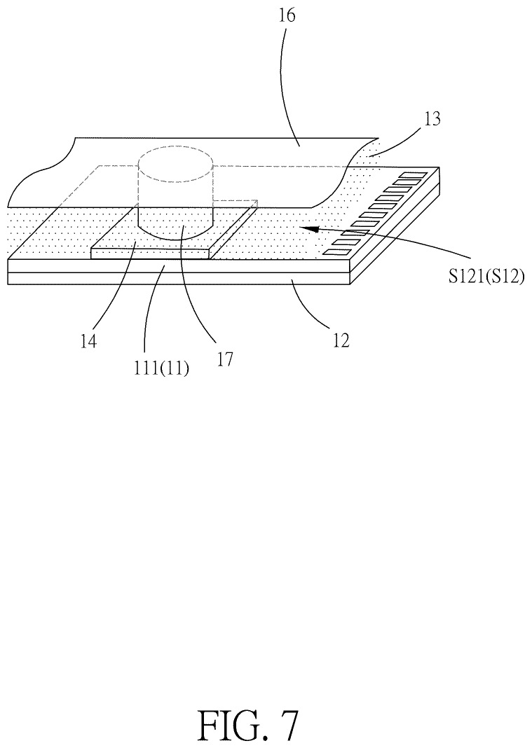

In the embodiment shown in FIG. 7, the optoelectronics transceiver device 1 further comprises a second cooling component 17. The second cooling component 17 is located in the base internal space S12. One end of the second cooling component 17 passes through the encapsulation film 14 and contacts the optoelectronics transceiver module processing section 111 to absorb heat therefrom, while the other end passes through the adhesive 13 and contacts the device cover 16 to conduct the absorbed heat from the optoelectronics transceiver module processing section 111 to the outside through the device cover 16, thereby achieving cooling.

Preferably, the device base 12 may be a heat-conductive metal base capable of conducting heat. The second cooling component 17 may be a heat-conductive metal component, and the device cover 16 may be a heat-conductive metal cover. The device base 12 may optionally be in contact with the device cover 16 to absorb heat from the cover, which comes from the optoelectronics transceiver module processing section 111, to cool the device cover 16 and thereby accelerate the cooling of the optoelectronics transceiver module processing section 111.

It should be noted that the optoelectronics transceiver device of the present application may omit certain components or structures and is not limited to the embodiments described above.

For example, the optoelectronics transceiver device of the present application may optionally comprise: an optoelectronics transceiver module, a device base, an adhesive, and an encapsulation film. The optoelectronics transceiver module comprises a processing section configured to convert a signal. The device base comprises a base internal space and is configured to carry the optoelectronics transceiver module to allow the optoelectronics transceiver module processing section to be accommodated therein. The adhesive is filled into the base internal space to form a sealing subspace in which the optoelectronics transceiver module processing section is located, thereby providing a sealed operating environment. The encapsulation film covers the optoelectronics transceiver module processing section in the base internal space to separate the optoelectronics transceiver module processing section from the adhesive.

In another example, the optoelectronics transceiver device of the present application may optionally comprise: an optoelectronics transceiver module and an encapsulation film. The optoelectronics transceiver module comprises a processing section configured to convert a signal. The encapsulation film covers the optoelectronics transceiver module processing section to form a sealing subspace, wherein the optoelectronics transceiver module processing section is located, and the sealing subspace provides a sealed operating environment.

In summary, the present application provides an optoelectronics transceiver device that can operate in a cooling liquid. The optoelectronics transceiver device comprises: an optoelectronics transceiver module and an encapsulation film. The optoelectronics transceiver module comprises an optoelectronics transceiver module processing section, and the encapsulation film covers the optoelectronics transceiver module processing section to provide a sealed operating environment. In this way, when the optoelectronics transceiver device operates in the liquid cooling environment, the encapsulation film can prevent the cooling liquid from seeping into the optoelectronics transceiver module processing section and affecting the operation of the optoelectronics transceiver module, thereby improving the performance and service life of the optoelectronics transceiver device.

The examples above are only illustrative to explain principles and effects of the invention, but not to limit the invention. It will be apparent to those skilled in the art that modifications and variations can be made without departing from the spirit and scope of the invention. Therefore, the protection range of the rights of the invention should be as defined by the appended claims.

What is claimed is:

1. An optoelectronics transceiver device, which is configured to transmit a signal, wherein the optoelectronics transceiver device comprises:
an optoelectronics transceiver module, which comprises an optoelectronics transceiver module processing section, and the optoelectronics transceiver module processing section is configured to perform optoelectronics transceiver processing on the signal;
a device base, which comprises a base internal space, and the device base is configured to carry the optoelectronics transceiver module, allowing the optoelectronics transceiver module processing section to be accommodated in the base internal space;
an adhesive, which is filled into the base internal space to form a sealing subspace within the base internal space, wherein the optoelectronics transceiver module processing section is located in the sealing subspace, and the sealing subspace provides a sealed operating environment for the optoelectronics transceiver module processing section; and
an encapsulation film, which covers the optoelectronics transceiver module processing section within the base internal space to separate the adhesive from the optoelectronics transceiver module processing section.

2. The optoelectronics transceiver device of claim 1, further comprising a first cooling component, and the first cooling component is located in the sealing subspace and is in contact with the optoelectronics transceiver module processing section to absorb heat and cool the optoelectronics transceiver module processing section; and the encapsulation film also covers the first cooling component to separate the adhesive from the first cooling component.

3. The optoelectronics transceiver device of claim 2, wherein the first cooling component is a water block and comprises a first cooling component liquid passage, and the first cooling component liquid passage is configured to allow cooling liquid to flow to cool the optoelectronics transceiver module processing section.

4. The optoelectronics transceiver device of claim 2, wherein the device base comprises a frame-shaped or U-shaped cross section.

5. The optoelectronics transceiver device of claim 2, wherein the first cooling component is a heat-conductive metal component.

6. The optoelectronics transceiver device of claim 1, further comprising a device cover, and the device cover is disposed on the device base so as to allow the adhesive to be located in the signal base internal space.

7. The optoelectronics transceiver device of claim 6, further comprising a second cooling component, which is located in the base internal space, one end of the second cooling component penetrates through the encapsulation film and is in contact with the optoelectronics transceiver module processing section to absorb heat from the optoelectronics transceiver module processing section, and the other end of the second cooling component penetrates through the adhesive and is in contact with the device cover to conduct the absorbed heat to the outside through the device cover, thereby achieving cooling of the optoelectronics transceiver module processing section.

8. The optoelectronics transceiver device of claim 7, wherein the device base is in contact with the device cover to absorb heat and cool the device cover.

9. The optoelectronics transceiver device of claim 7, wherein the device base is a heat-conductive metal base; the second cooling component is a heat-conductive metal component; and the device cover is a heat-conductive metal cover.

10. The optoelectronics transceiver device of claim 1, further comprising a signal optical cable, and the signal optical cable penetrates through the adhesive and the encapsulation film to connect to the optoelectronics transceiver module processing section for transmitting the signal.

11. The optoelectronics transceiver device of claim 1, which is configured to be equipped with an optical fiber network equipment, wherein the optoelectronics transceiver module further comprises an optoelectronics transceiver module joining section, the device base comprises a base joining port, and the optoelectronics transceiver module joining section is located at the base joining port to provide joining to the optical fiber network equipment, and the optoelectronics transceiver device further comprises a stopper body, and the stopper body is located between the base internal space and the base joining port to block the adhesive from entering the base joining port from the base internal space.

12. The optoelectronics transceiver device of claim 1, wherein the stopper body and the device base are integrally formed.

13. An optoelectronics transceiver device, which is configured to transmit a signal, wherein the optoelectronics transceiver device comprises:
an optoelectronics transceiver module, comprising an optoelectronics transceiver module processing section, and the optoelectronics transceiver module processing section is configured to perform optoelectronics transceiver processing on the signal; and
an encapsulation film, which covers the optoelectronics transceiver module processing section to form a sealing subspace, wherein the optoelectronics transceiver module processing section is located in the sealing subspace, and the sealing subspace provides a sealed operating environment for the optoelectronics transceiver module processing section.
